(19) United States
(12) Patent Application Publication
(10) Pub. No.: US 2026/0177588 A1
(43) Pub. Date: Jun. 25, 2026

(54) SHUNT RESISTOR AND SHUNT RESISTANCE DEVICE

(71) Applicant: KOA CORPORATION, Ina-shi, Nagano (JP)

(72) Inventors: Shuhei Matsubara, Ina-shi, Nagano (JP); Susumu Toyoda, Ina-shi, Nagano (JP); Koichi Hirasawa, Ina-shi, Nagano (JP); Keishi Nakamura, Ina-shi, Nagano (JP)

(73) Assignee: KOA CORPORATION, Ina-shi, Nagano (JP)

(21) Appl. No.: 18/854,800

(22) PCT Filed: Feb. 22, 2023
(86) PCT No.: PCT/JP2023/006418

§ 371 Date: Oct. 7, 2024

(30) Foreign Application Priority Data
Apr. 12, 2022 (JP) 2022-065814

(51) Int. Cl. G01R 15/14; G01R 1/20; G01R 31/364; H01C 1/144; H01C 1/148

(52) U.S. Cl. CPC G01R 15/146; G01R 1/20; G01R 1/203; G01R 31/364; H01C 1/144; H01C 1/148

(57) ABSTRACT

The present invention relates to a shunt resistor and a shunt resistance device. The shunt resistor (1) includes at least two laminated elements (50) having a resistive elements (5) and attached to an electrode member (10). The electrode member (10) has at least two contact portions (10a) that contact the at least two laminated elements (50).

### TECHNICAL FIELD

The present invention relates to a shunt resistor and a shunt resistance device.

### BACKGROUND ART

There is a shunt resistor in which a current is passed through a resistance element and a magnitude of the current is detected from a voltage at both ends of the resistance element (e.g., see patent document 1). Such a shunt resistor includes a disc-shaped resistance element and two electrodes formed on both sides of the resistance element. One of the two electrodes is connected to a wire (pad), and the other is connected to a bonding wire.

### CITATION LIST

### Patent Literature

Patent document 1: Japanese laid-open patent publication No. 2018-170478

### SUMMARY OF INVENTION

### Technical Problem

The electrode connected to a bonding wire has a potential distribution. Therefore, if a connection position of the bonding wire is shifted, the detected resistance value and a temperature coefficient of resistance (TCR) of the shunt resistor may change. The temperature coefficient of resistance is an index that indicates a rate of change in resistance value due to temperature.

In a surface mount type shunt resistor as described above, it is not possible to grasp its state (presence or absence of failure, risk of failure, etc.). Therefore, even if the shunt resistor fails or is likely to fail due to the application of a large current or other cause, it is not possible to predict or detect the failure of the shunt resistor.

Therefore, the present invention provides a shunt resistor and a shunt resistance device whose state can be grasped.

### Solution to Problem

In an embodiment, there is provided a shunt resistor, comprising: an electrode member made of a conductive material; and at least two laminated elements having a resistance element, and attached to the electrode member, the electrode member has at least two contact portions configured to contact at least two laminated elements.

In an embodiment, the electrode member comprises an electrode-member side slit formed in the contact portion.

In an embodiment, the laminated element comprises a first electrode arranged on an opposite side of the electrode member, sandwiching the resistance element.

In an embodiment, the laminated element comprises a second electrode arranged between the resistance element and the electrode member.

In an embodiment, the laminated element comprises a laminated-element side slit formed in the second electrode.

In an embodiment, the electrode member has a structure that allows an adjustment of a temperature coefficient of resistance, which is an index showing a rate of change in resistance value with temperature, depending on a thickness of the electrode member.

In an embodiment, there is provided a shunt resistance device, comprising: a shunt resistor described above; at least two voltage detection wires connected to the at least two contact portions; and at least two voltage detection wires connectable to an inner region of a current-carrying pattern for placing the at least two laminated elements, the current-carrying pattern has a notch portion formed in the inner region.

In an embodiment, the electrode member comprises an electrode-member side slit formed in the contact portions, and each of the at least two voltage detection wires connected to the at least two contact portions is arranged in a wiring area between the electrode-member side slit and an end portion of the electrode member.

### Advantageous Effects of Invention

By arranging at least two laminated elements, a state of the shunt resistor can be grasped.

### BRIEF DESCRIPTION OF DRAWINGS

FIG. 1 is a perspective view showing one embodiment of a shunt resistor for current detection;

FIG. 2 is a vertical cross-sectional view of the shunt resistor shown in FIG. 1;

FIG. 3 is a view showing the shunt resistor mounted on a mounting land pattern;

FIG. 4A is a view showing another embodiment of an electrode member;

FIG. 4B is a view showing another embodiment of the electrode member;

FIG. 5A is a view showing another embodiment of the current-carrying pattern;

FIG. 5B is a view showing another embodiment of the current-carrying pattern;

FIG. 6 is a view showing a current path formed by the current-carrying pattern and the shunt resistor;

FIG. 7 is a view showing the current path formed by the current-carrying pattern and the shunt resistor;

FIG. 8 is a view showing the current path formed by the current-carrying pattern and the shunt resistor;

FIG. 9 is a view showing the current path formed by the current-carrying pattern and the shunt resistor;

FIG. 10 is a view showing another embodiment of the shunt resistor;

FIG. 11 is a view showing another embodiment of the shunt resistor; and

FIG. 12 is a view showing a slit formed in a second electrode.

### DESCRIPTION OF EMBODIMENTS

Embodiments of the invention will be described below with reference to the drawings. In the drawings described below, identical or equivalent components will be marked with the same symbol and redundant explanations will be omitted.

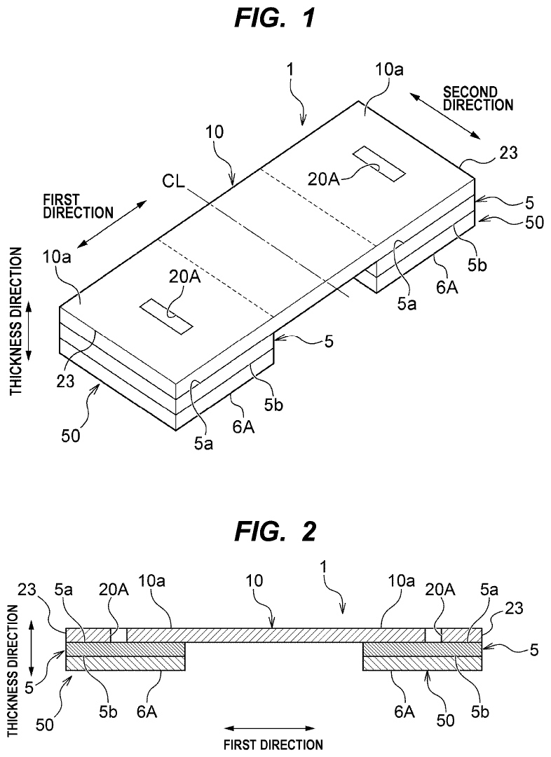

FIG. 1 is a perspective view showing one embodiment of a shunt resistor for current detection. FIG. 2 is a vertical cross-sectional view of the shunt resistor shown in FIG. 1. As shown in FIGS. 1 and 2, the shunt resistor 1 includes an electrode member 10 made of a conductive material, and at least two laminated elements 50 attached to the electrode member 10. In the embodiment shown in FIGS. 1 and 2, the shunt resistor 1 includes two laminated elements 50, but may include three or more laminated elements 50.

The laminated element 50 includes a plate-shaped (thin plate-shaped) resistance element 5 having a predetermined thickness and width, and a plate-shaped (thin plate-shaped) electrode (first electrode) 6A made of a conductive material. The electrode 6A is arranged on an opposite side of the electrode member 10, sandwiching the resistance element 5 therebetween.

An example of the material of the resistance element 5 is a resistive alloy material such as a Cu—Mn—Ni based alloy or a Ni—Cr based alloy. An example of the material of the electrode 6A and the electrode member 10 is copper (Cu), which is a highly conductive metal.

The resistance element 5 has a first-resistance-element surface 5a and a second-resistance-element surface 5b which is a surface opposite to the first-resistance-surface 5a. The electrode member 10 is connected to the first-resistance-element surface 5a, and the electrode 6A is connected to the second-resistance-element surface 5b. That is, the electrode 6A, the resistance element 5, and the electrode member 10 are layered in this order in a thickness direction of the shunt resistor 1.

In FIGS. 1 and 2, the thickness direction of the shunt resistor 1 is parallel to a vertical direction. A first direction is a length direction of the shunt resistor 1 and is parallel to a current direction passing through the shunt resistor 1. A second direction is a width direction of the shunt resistor 1 and is perpendicular to the first direction.

The electrode member 10 has contact portions 10a that come into contact with the laminated elements 50 (in this embodiment, the resistance element 5 and the electrode 6A). The number of contact portions 10a corresponds to the number of laminated elements 50. In this embodiment, the shunt resistor 1 has two laminated elements 50, and therefore the electrode member 10 has two contact portions 10a.

The two laminated elements 50 are arranged symmetrically with respect to a center line CL of the electrode member 10, and are arranged in series with and spaced apart from the electrode member 10 in the first direction of the shunt resistor 1. The center line CL is an imaginary line segment that extends parallel to the second direction of the shunt resistor 1 and bisects the electrode member 10. The electrode member 10 has both end portions 23 in the first direction.

The electrode member 10 may be connected to the first-resistance-element surface 5a of the resistance element 5 by a connection means such as a conductive adhesive such as metal nanoparticles (silver paste using silver nanoparticles or copper paste using copper nanoparticles), welding such as pressure welding, or solder. The electrode 6A may also be connected to the second-resistance-element surface 5b of the resistor 5 by a similar connection means. The electrode 6A is subjected to a surface treatment such as Sn plating or Ni plating to enable solder mounting. The surface plating of the electrode 6A may not be required.

The electrode member 10 has a structure that allows a temperature coefficient of resistance (TCR), which is an index showing a rate of change in resistance value due to temperature, to be adjusted by the thickness of the electrode member 10. More specifically, an accuracy of the TCR can be improved by adjusting the thickness of the electrode member 10. For example, the TCR can be reduced by reducing the thickness of the electrode member 10. In one embodiment, the electrode member 10 may have the same thickness as the resistance element 5, or may have a thickness thinner than the resistance element 5.

As shown in FIGS. 1 and 2, the electrode member 10 includes a slit (more specifically, an electrode-member side slit) 20A formed in the contact portion 10a. In this manner, by forming the slit in the contact portion 10a of the electrode member 10, the TCR can be adjusted. In this embodiment, the slit 20A is a long hole extending in a direction perpendicular to the current direction (i.e., a direction parallel to the second direction), and penetrates from a surface of the electrode member 10 to reach the resistance element 5. In one embodiment, the slit 20A may be a depression formed in the surface of the electrode member 10. Each of the both end portions 23 is adjacent to the slit 20A formed in the contact portion 10a.

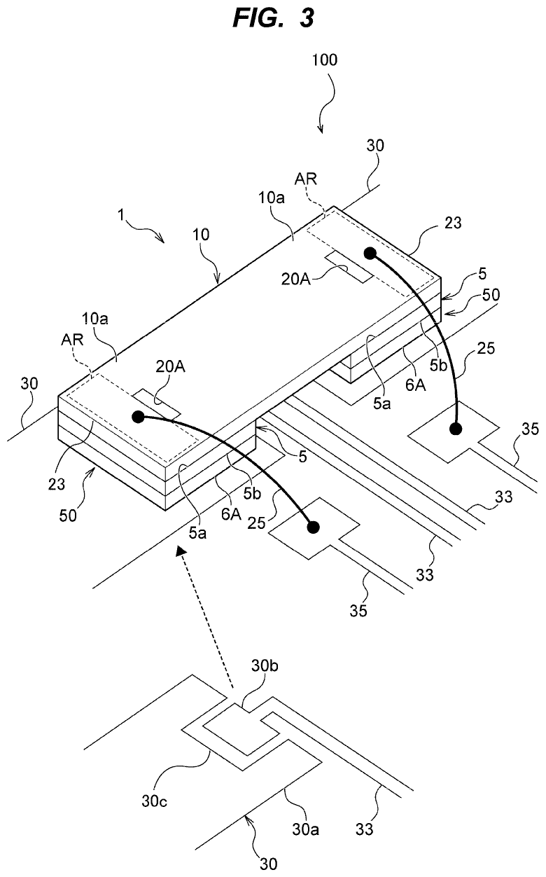

FIG. 3 is a view showing a shunt resistor mounted on a mounting land pattern. As shown in FIG. 3, the shunt resistor 1 has a wiring area AR (a frame surrounded by a dotted line in FIG. 3) arranged between the slit 20A and the both end portions 23. The wiring area AR constitutes a part of the contact portion 10a, and one end of a voltage detection wire 25 is connected to the wiring area AR during mounting. The other end of the voltage detection wire 25 is connected to a connector 35.

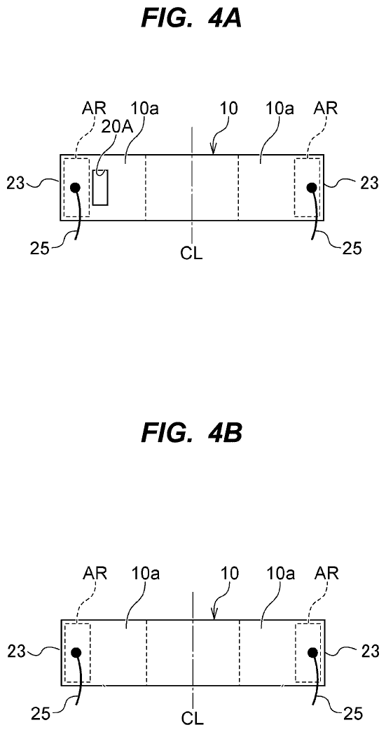

FIGS. 4A and 4B are views showing other embodiments of the electrode member. As shown in FIG. 4A, the electrode member 10 may have the slit 20A formed in either of the two contact portions 10a. As shown in FIG. 4B, the electrode member 10 may not have the slit 20A. In the embodiment shown in FIG. 4B, the wiring area AR is formed in a region adjacent to the both end portions 23.

The voltage detection wire 25 is a wire (terminal) for detecting a potential difference between the electrode member 10 and the voltage detection wire 33. The laminated element 50, the electrode member 10, and the voltage detection wire 25 connected to the electrode member 10 constitute a shunt resistance device 100.

The number of the voltage detection wires 25 corresponds to the number of the laminated elements 50. Therefore, the shunt resistance device 100 includes at least two voltage detection wires 25 connected to at least two contact portions 10a. In one embodiment, the voltage detection wires 25 may be bonding wires. In this case, the wiring area AR of the electrode member 10 (more specifically, the contact portion 10a) is subjected to a surface treatment (e.g., NiP plating, Ni plating, etc.) that enables bonding. The surface treatment of the electrode member 10 may not be required.

As shown in FIG. 3, the shunt resistor 1 is arranged on adjacent current-carrying patterns 30. A voltage detection wire (lead wire) 33 is arranged between the current-carrying patterns 30. The lead wire 33 is a voltage detection terminal for detecting a potential difference generated between the lead wire 33 and the electrode member 10. The current-carrying patterns 30 are formed on a circuit board such as a printed circuit board (not shown). The laminated element 50 (more specifically, the electrode 6A) is connected (joined) to the current-carrying patterns 30 by means of solder or the like.

The current-carrying pattern 30 has a main body portion 30a, an inner region 30b arranged inside the main body portion 30a, and a notch portion 30c formed in the inner region 30b and dividing the main body portion 30a from the inner region 30b. In the embodiment shown in FIG. 3, the notch portion 30c completely separates the main body portion 30a from the inner region 30b, and the laminated element 50 is connected to the inner region 30b and a part of the main body portion 30a of the current-carrying pattern 30. The lead wire 33 is connected to the inner region 30b of the current-carrying pattern 30.

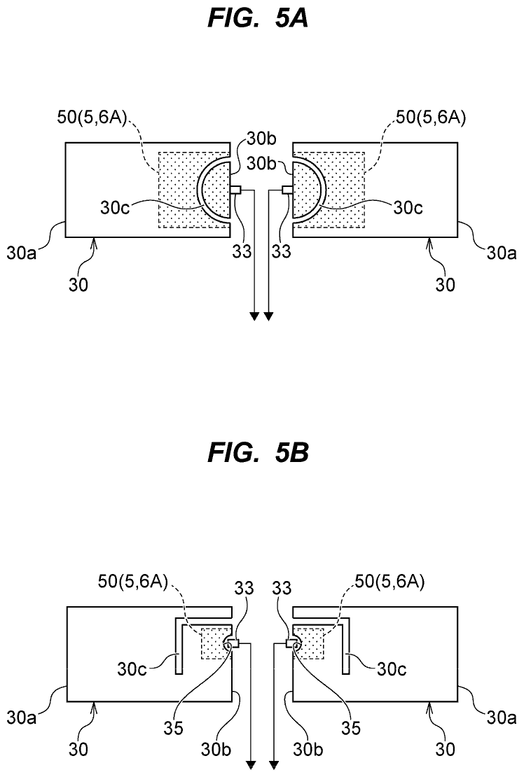

FIGS. 5A and 5B are views showing other embodiments of the current-carrying pattern. In the embodiment shown in FIG. 5A, the notch portion 30c has an are shape and completely separates the main body 30a and the inner region 30b. In the embodiment shown in FIG. 5B, the notch portion 30c has an L-shape, and the main body 30a and the inner region 30b are connected. The lead wire 33 is not directly connected to the inner region 30b of the current-carrying pattern 30, but is spaced apart. Note that the electrode 6A when the laminated element 50 is connected to the current-carrying pattern is shown in the drawing.

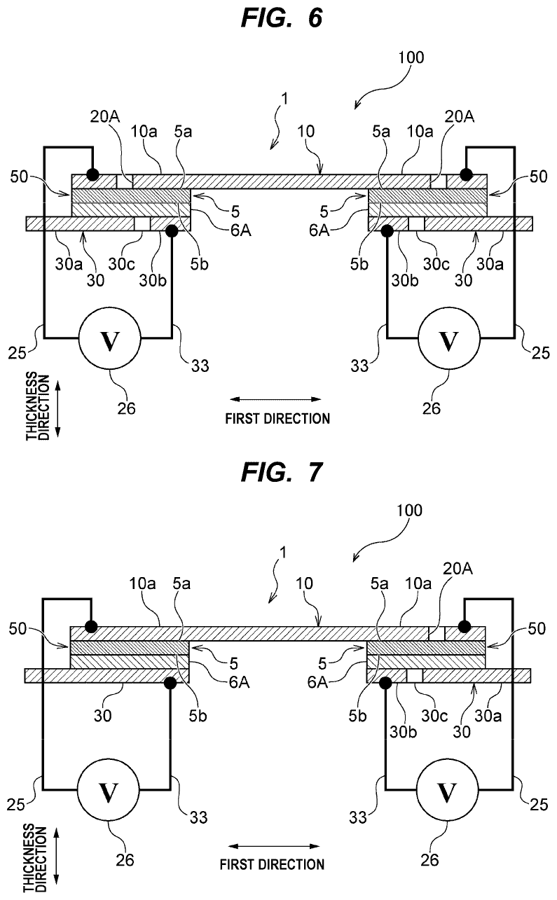

FIGS. 6 through 9 are views showing a current path formed by the current-carrying pattern and the shunt resistor. The voltage detection wire 25 is connected to the electrode member 10 of the shunt resistor 1, and the lead wire 33 is connected to the current-carrying pattern 30, forming the current path that flows from the current-carrying pattern 30 in the thickness direction of the shunt resistor 1. In this embodiment, a voltage measurement device 26 is used to measure the potential difference (i.e., the potential difference in the resistance element 5) between the voltage detection wire 25 and the lead wire 33. The current value is calculated by measuring this potential difference.

According to the embodiment, the shunt resistor 1 includes at least two laminated elements 50, and is configured to measure a potential difference in each laminated element 50. When an abnormality occurs in the shunt resistor 1, a resistance value of the abnormal laminated element 50 changes. According to the embodiment, by arranging at least two laminated elements 50 and comparing the resistance values of the laminated elements 50, the state of the shunt resistor 1 can be grasped. Therefore, even if the shunt resistor 1 fails or is likely to fail, it is possible to predict or detect the failure of the shunt resistor 1.

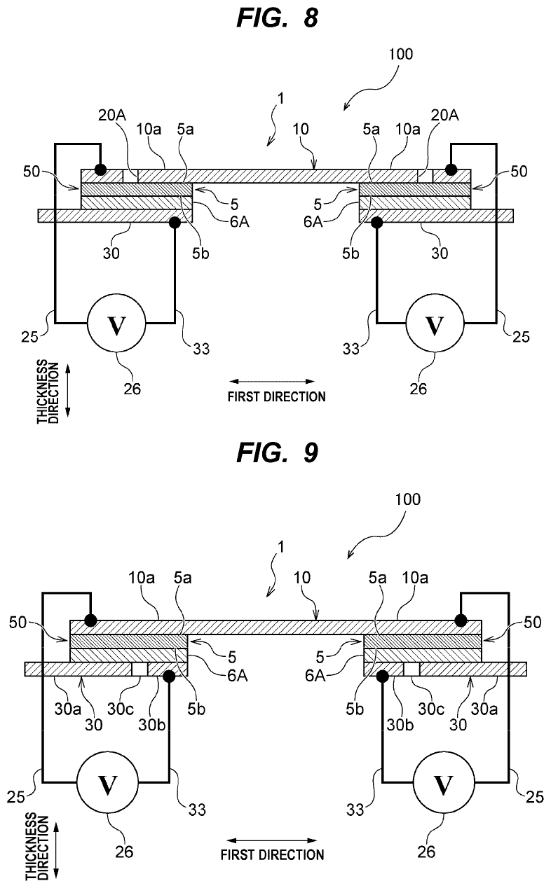

In the embodiment shown in FIG. 6, the shunt resistor 1 has the number of slits 20A corresponding to the number of laminated elements 50, and the current-carrying pattern 30 has the number of notch portions 30c corresponding to the number of laminated elements 50. In the embodiment shown in FIG. 7, the shunt resistor 1 has a single slit 20A, and the current-carrying pattern 30 has a single notch portion 30c. In the embodiment shown in FIG. 8, the shunt resistor 1 has the number of slits 20A corresponding to the number of laminated elements 50, but the current-carrying pattern 30 does not have the notch portion 30c. In the embodiment shown in FIG. 9, the shunt resistor 1 does not have a slit 20A, and the current-carrying pattern 30 has the number of notch portions 30c corresponding to the number of laminated elements 50.

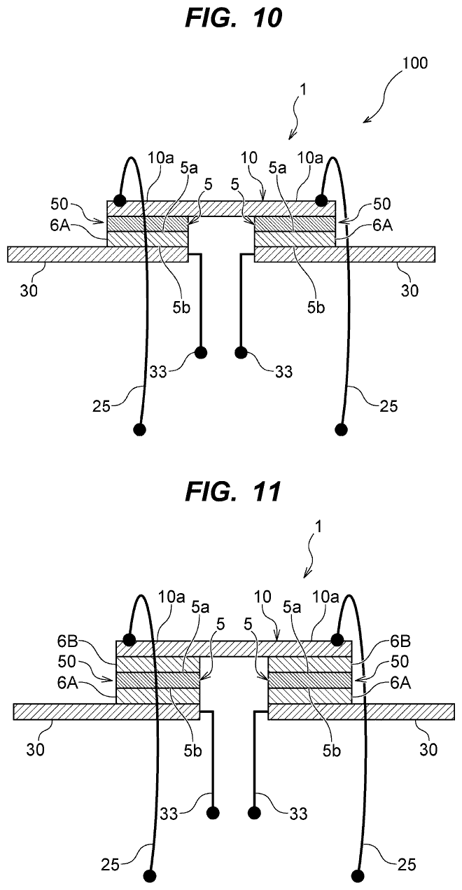

FIG. 10 is a view showing another embodiment of the shunt resistor. In the above-described embodiment, the shunt resistor 1 has at least one of the slit 20A and the notch portion 30c, but as shown in FIG. 10, the shunt resistor 1 does not have to have either the slit 20A or the notch portion 30c.

FIG. 11 is a view showing another embodiment of the shunt resistor. As shown in FIG. 11, the laminated element 50 may include an electrode (second electrode) 6B arranged between the resistance element 5 and the electrode member 10.

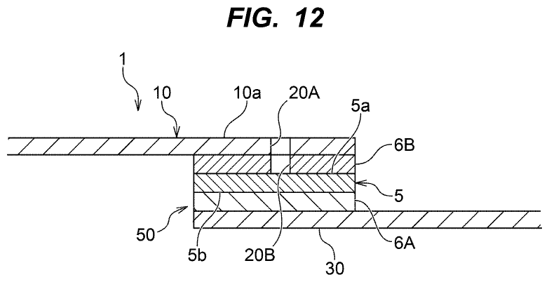

FIG. 12 is a view showing a slit formed in the second electrode. As shown in FIG. 12, the laminated element 50 may include a laminated-element side slit 20B formed in the second electrode 6B. In the embodiment shown in FIG. 12, the electrode-member side slit 20A and the laminated-element side slit 20B penetrate to reach the resistance element 5, but in one embodiment, the electrode-member side slit 20A may be a depression formed in the surface of the electrode member 10. Alternatively, the electrode-member side slit 20A may be a through hole to the second electrode 6B. Since the TCR is affected by the width, length, and formation position of the slit, it is desirable to form the slit so as to ensure a good TCR. In the embodiment shown in FIG. 12, the current-carrying pattern 30 does not have the notch portion 30c, but may have the notch portion 30c.

The above embodiments are described for the purpose of practicing the present invention by a person with ordinary skill in the art to which the invention pertains. Although preferred embodiments have been described in detail above, it should be understood that the present invention is not limited to the illustrated embodiments, but many changes and modifications can be made therein without departing from the appended claims.

### INDUSTRIAL APPLICABILITY

The present invention is applicable to a shunt resistor and a shunt resistance device.

### REFERENCE SIGNS LIST

1 shunt resistor
5 resistance element
5a first-resistance-element surface
5b second-resistance-element surface
6A first electrode
6B second electrode
10 electrode member
10a contact portion
20A slit (electrode-member side slit)
20B slit (laminated-element side slit)
23 both end portion
25 voltage detection wire
26 voltage measurement device
30 current-carrying pattern
30a main body portion
30b inner region
30c notch portion
33 voltage detection wire (lead wire)
35 connector
50 laminated element
100 shunt resistance device
CL center line
AR wiring area

1. A shunt resistor, comprising:
an electrode member made of a conductive material; and
at least two laminated elements having a resistance element, and attached to the electrode member,
wherein the electrode member has at least two contact portions configured to contact at least two laminated elements.

2. The shunt resistor according to claim 1, wherein the electrode member comprises an electrode-member side slit formed in the contact portion.

3. The shunt resistor according to claim 1, wherein the laminated element comprises a first electrode arranged on an opposite side of the electrode member, sandwiching the resistance element.

4. The shunt resistor according to claim 3, wherein the laminated element comprises a second electrode arranged between the resistance element and the electrode member.

5. The shunt resistor according to claim 4, wherein the laminated element comprises a laminated-element side slit formed in the second electrode.

6. The shunt resistor according to claim 1, wherein the electrode member has a structure that allows an adjustment of a temperature coefficient of resistance, which is an index showing a rate of change in resistance value with temperature, depending on a thickness of the electrode member.

7. A shunt resistance device, comprising:
a shunt resistor according to claim 1;
at least two voltage detection wires connected to the at least two contact portions; and
at least two voltage detection wires connectable to an inner region of a current-carrying pattern for placing the at least two laminated elements,
wherein the current-carrying pattern has a notch portion formed in the inner region.

8. The shunt resistance device according to claim 7, wherein the electrode member comprises an electrode-member side slit formed in the contact portions, and
wherein each of the at least two voltage detection wires connected to the at least two contact portions is arranged in a wiring area between the electrode-member side slit and an end portion of the electrode member.
